(19) United States
(12) Patent Application Publication
(10) Pub. No.: US 2003/0228417 A1
(43) Pub. Date: Dec. 11, 2003

(54) Evaporation method and manufacturing method of display device

(75) Inventors: Ryuji Nishikawa, Gifu-shi (JP); Tsutomu Yamada, Motosu-gun (JP)

Correspondence Address: MORRISON & FOERSTER LLP, 1650 TYSONS BOULEVARD, SUITE 300, MCLEAN, VA, 22102, US

(73) Assignee: Sanyo Electric Co., Ltd., Moriguchi-City (JP)

(21) Appl. No.: 10/400,925

(22) Filed: Mar. 28, 2003

(30) Foreign Application Priority Data
Mar. 29, 2002 (JP) 2002-095993

(51) Int. Cl. B05D 5/06; B05D 5/12; C23C 16/00; B05D 1/32

(52) U.S. Cl. 427/248.1; 427/66; 427/282

(57) ABSTRACT

The evaporation method of this invention comprises a process for tightly placing an evaporation mask on a substrate, and a process for disposing an evaporation material on the surface of the substrate through a plurality of openings formed in the evaporation mask by moving a plurality evaporation sources along the entire length of the substrate for forming a pattern. The evaporation sources are loaded with different evaporation materials. A plurality of evaporation layers can be continuously disposed on the substrate by sequentially or simultaneously moving the evaporation source.

### BACKGROUND OF THE INVENTION

1. Field of Invention

This invention relates to an evaporation method and a manufacturing method of a display device, especially to an evaporation method and the manufacturing method of a display device for providing pixel elements with improved display qualities.

2. Description of the Related Art

EL (electroluminescent) display devices with an EL element have been gathering attention as a display device substituting a CRT and an LCD. The development effort for the EL display device with a thin film transistor (referred to as TFT hereinafter) as a switching device for driving the EL element has been made accordingly.

FIG. 11 is a plan view showing the vicinity of a display pixel of an organic EL display device. FIG. 12A shows a cross-sectional view of the device along the A-A cross-sectional line, and FIG. 12B shows a cross-sectional view of the device along the B-B cross-sectional line in FIG. 11.

As seen from FIGS. 11, 12A, and 12B, the display pixel 115 is formed in an area surrounded with a gate signal line 51 and a drain signal line 52. The display pixels are disposed as a matrix configuration.

An organic EL element 60, which is a light-emitting device, a switching TFT 30 for controlling the timing of supplying electric current to the organic EL element 60, a driving TFT 40 for supplying electric current to the organic EL element 60, and a storage capacitance element 56 are disposed in the display pixel 115. The organic EL element 60 includes an anode 61, a hole transport layer 62, an emissive layer 63, an electron transport layer 64 and a cathode 65.

The switching TFT 30 is disposed near the crossing of the signal lines 51, 52. A source 33s of the TFT 30 functions also as a capacitance electrode 55 that forms capacitance with a storage capacitance electrode line 54, and is connected to a gate 41 of the EL element driving TFT 40. A source 43s of the second TFT is connected to the anode 61 of the organic EL element 60 and a drain 43d is connected to a driving source line 53 that is the source of the electric power supplied to the organic EL element 60.

The storage capacitance electrode line 54 is disposed in parallel with the gate signal line 51. The storage capacitance electrode line 54 is made of chrome and forms capacitance by accumulating electric charge with the capacitance electrode 55 connected to the source 33s of the TFT through a gate insulating film 12. A storage capacitance element 56 is disposed to store the voltage applied to a gate electrode 41 of the second TFT 40.

The TFTs 30,40 and the organic EL element 60 are sequentially disposed on a substrate 10, which may be a glass substrate, a resin substrate, a conductive substrate or a semiconductor substrate, as shown FIGS. 11A and 11B. When the conductive substrate or the semiconductor substrate is used as the substrate 10, an insulating film made of SiO₂ or SiN should be disposed on the substrate first. Then TFTs 30, 40 and the organic EL element are formed. Both TFTs 30,40 have a top-gate configuration, where the gate electrode is located above an active layer with the gate insulating film between them.

The explanation on the switching TFT will be made hereinafter.

As shown in FIG. 12A, an amorphous silicon film (referred to as a-Si film hereinafter) is formed through a CVD method on the insulating substrate 10, which is made of a quartz glass or a non-alkaline glass. A laser beam is lead to the a-Si film for re-crystallization from melt, forming a poly-crystalline silicon film (referred to as a p-Si film, hereinafter). This functions as the active layer 33. Single layer or multiple layers of a SiO₂ film and a SiN film are formed on the p-Si film as the insulating film 12, on which the gate signal line 51 also working as the gate electrode 31 made of a metal with a high-melting point such as Cr and Mo and the drain signal line 52 made of Al are disposed. The driving source line 53 made of Al that is the source of the driving power of the organic EL element is also disposed.

A SiO₂ film, a SiN film and a SiO₂ film are sequentially disposed to form an interlayer insulating film 15 on the entire surface of the gate insulating film 32 and the active layer 33. A drain electrode 36, which is formed by filling a contact hole formed corresponding to the drain 33d with a metal such as Al, is disposed, and a flattening insulating film 17 made of an organic resin for flattening the surface is formed on the entire surface.

Next, the description on the TFT 40 for driving the organic EL element, will be provided. As shown in FIG. 12B, an active layer 43, which is formed by illuminating with the laser beam for poly-crystallization, a gate insulating film 12, and a gate electrode 41 made of a metal with a high-melting point such as Cr and Mo are sequentially disposed on the insulating substrate 10, which is made of a quartz glass or a non-alkaline glass. A channel 43c, and a source 43s and a drain 43d located both sides of the channel 43c are formed in the active layer 43. A SiO₂ film, a SiN film and a SiO₂ film are sequentially disposed to form the interlayer insulating film 15 on the entire surface of the gate insulating film 12 and the active layer 43. The driving source line 53, which is connected to the driving source by filling a contact hole formed corresponding to the drain 43d with a metal such as Al, is disposed. Furthermore, the flattening insulating film 17 made of an organic resin for flattening the surface is formed on the entire surface. A contact hole corresponding to the location of the source 43s is formed in the flattening film 17. A transparent electrode made of ITO (indium tin oxide) that is the anode 61 of the organic EL element making a contact with the source 43s through the contact hole is formed on the flattening film 17. The anode 61 is formed separately, forming an island for each of the display pixel .

The organic EL element 60 includes the anode 61 made of the transparent electrode such as ITO, a hole transportation layer 62 including a first hole transportation layer made of MTDATA (4,4-bis (3-mathylphenylphenylamino)biphenyl) and a second hole transportation layer made of TPD (4,4,4-tris (3-methylphenylphenylamino) triphenylanine), an emissive layer 63 made of Bebq2 (bis(10-hydroxybenzo[h]quinolinato)beryllium) including quinacridone derivative, an electron transportation layer 64 made of Bebq2, and the cathode 65 made of either magnesium-indium alloy, aluminum, or aluminum alloy.

In the organic EL element 60, a hole injected from the anode 61 and an electron injected from the cathode 65 are recombined in the emissive layer and an exciton is formed by exciting an organic module of the emissive layer 63. Light is emitted from the emissive layer 63 in a process of relaxation of the exciton and then released outside after going through the transparent anode 61 and the transparent insulating substrate 10.

This technology is described in, for example, Japanese Laid-Open Patent Publication No. H 11-283182.

The organic EL material used in the hole transportation layer 62, the emissive layer 63, and the electron transportation layer 64 of the organic EL element 60 has a low anti-solvent property and it is vulnerable to water. Therefore, the photolithographic technology of the semiconductor process can not be utilized. Thus, the hole transportation layer 62, the emissive layer 63, and the electron transportation layer 64 of the organic EL element 60 are formed by evaporation using a shadow mask.

Next, the pattern forming method through evaporation of the organic EL material will be explained by referring to FIGS. 13-16. The reference numeral 100 indicates a vacuum evaporation device, the reference numeral 101 an exhaust system attached to the vacuum evaporation device, and the reference numeral 110 a supporting table in the chamber of the vacuum evaporation device. A shadow mask (an evaporation mask) 111 made of magnetic material such as nickel (Ni) or invar alloy (Fe64Ni36) is disposed on the supporting table 110. A plurality of opening portions 112 is formed in the predetermined locations of the shadow mask 111.

A magnet 120, which is movable in vertical direction, is disposed on the shadow mask 111 on the supporting table 110. The reference numeral 130 indicates a glass substrate known as a mother glass inserted between the magnet 120 and the shadow mask 111. The reference numeral 140 denotes an evaporation source located underneath the shadow mask 111 and movable in the horizontal direction along the shadow mask 111.

The chamber of the vacuum evaporation device 100 is evacuated by the exhaust system 101, in FIG. 13. The glass substrate 130 is inserted between the magnet 120 and the shadow mask 111 by a transportation system not shown in the figure. Then the glass substrate 130 is placed on the shadow mask 111 by the transportation system as seen from FIG. 14.

Then, the magnet 120 is moved downwards to touch the upper surface of the glass substrate 130 as shown in FIG. 15. The shadow mask 111, receiving magnetic power from the magnet 120, is tightly placed to the lower surface of the glass substrate 130, on which a pattern will be formed.

The evaporation source 140 is moved in the horizontal direction from left edge to the right edge of the glass substrate 130, as seen from FIG. 16, by a moving system not shown in the figure. While the evaporation source is moving, the organic EL material or the material for the cathode 65 (for example, aluminum) evaporates and is deposited on the surface of the glass substrate 130 through the opening portions 112 of the shadow mask 111. The evaporation source 140 is a crucible extended in the vertical direction of the FIG. 15. The evaporation material in the crucible is heated by a heater for evaporation.

The magnet 120 moves upwards when the evaporation is finished. The glass substrate 130 is lifted from the shadow mask 111 and moved to the location of the next operation by the transportation system. This completes the pattern forming of the organic El element 60.

A multi-chamber method, where each layer is formed through the above evaporation method inside each chamber, has been employed for forming the hole transportation layer 62, the emissive layer 63, and the electron transportation layer 64 on the anode 61 made of ITO.

However, the hole transportation layer 62, the emissive layer 63 and the electron transportation layer 64 can not be formed continuously in the same chamber by the conventional evaporation method described above. Therefore, the interface of the layers may be contaminated, leading to the unstable property and the deterioration of the organic El element.

Also, the thickness of and the material for each layer can not be adjusted for each pixel of R, G, or B, in case of a full color organic El element display device that has the display pixel for each R, G, and B.

Therefore, this invention is directed to the continuous pattering through the formation of a plurality of the evaporation layers made of different materials and the evaporation method capable of achieving the most effective thickness for each of the evaporation layers and accommodating the most effective material for each of the evaporation layers.

### SUMMARY OF THE INVENTION

The invention provides an evaporation method that includes introducing an evaporation mask and a substrate into a vacuum chamber, evacuating the vacuum chamber to create a vacuum, and placing the evaporation mask on a surface of the substrate. The method also includes moving a first evaporation source having a first evaporation material therein in the vacuum along a first direction to deposit the first evaporation material on the surface of the substrate, and moving a second evaporation source having a second evaporation material therein in the vacuum along a second direction to deposit the second evaporation material on the first evaporation material deposited on the surface of the substrate.

The invention also provides a manufacturing method of a display device including an electroluminescent element. The method includes introducing an insulating substrate and an evaporation mask having openings corresponding to a pixel pattern of the display device into a vacuum chamber, evacuating the vacuum chamber to create a vacuum, and placing the evaporation mask on a surface of the insulating substrate. The method also includes moving a first evaporation source having a first constituent material of the electroluminescent element therein in the vacuum along a first direction to deposit the first constituent material on the surface of the insulating substrate, and moving a second evaporation source having a second constituent material of the electroluminescent element therein in the vacuum along a second direction to deposit the second constituent material on the first constituent material deposited on the surface of the insulating substrate.

The invention further provides a manufacturing method of a display device including electroluminescent elements corresponding to multiple colors. The method includes providing a deposition apparatus comprising a first evaporation chamber, a second evaporation chamber and a third evaporation chamber, introducing an insulating substrate and a pixel mask for a first color having openings corresponding to a pixel pattern of the first color into the first evaporation chamber, and placing the pixel mask for the first color on a surface of the insulating substrate. The method further includes moving a first evaporation source of the first color having therein a first constituent material of the electroluminescent element corresponding to the first color along a first direction to deposit the first constituent material of the first color on the surface of the insulating substrate and moving a second evaporation source of the first color having therein a second constituent material of the electroluminescent element corresponding to the first color along a second direction to deposit the second constituent material of the first color on the first constituent material of the first color deposited on the surface of the insulating substrate. The method also includes moving the insulating substrate from the first evaporation chamber to the second evaporation chamber, introducing a pixel mask for a second color having openings corresponding to a pixel pattern of the second color into the second evaporation chamber, and placing the pixel mask for the second color on the surface of the insulating substrate. The method further includes moving a first evaporation source of the second color having therein a first constituent material of the electroluminescent element corresponding to the second color along a third direction to deposit the first constituent material of the second color on the surface of the insulating substrate, and moving a second evaporation source of the second color having therein a second constituent material of the electroluminescent element corresponding to the second color along a fourth direction to deposit the second constituent material of the second color on the first constituent material of the second color deposited on the surface of the insulating substrate. The method also includes moving the insulating substrate from the second evaporation chamber to the third evaporation chamber, introducing a pixel mask for a third color having openings corresponding to a pixel pattern of the third color into the third evaporation chamber, and placing the pixel mask for the third color on the surface of the insulating substrate. The method further includes moving a first evaporation source of the third color having therein a first constituent material of the electroluminescent element corresponding to the third color along a fifth direction to deposit the first constituent material of the third color on the surface of the insulating substrate, and moving a second evaporation source of the third color having therein a second constituent material of the electroluminescent element corresponding to the third color along a sixth direction to deposit the second constituent material of the third color on the first constituent material of the third color deposited on the surface of the insulating substrate.

### BRIEF DESCRIPTION OF THE DRAWINGS

FIG. 1 shows a step of a manufacturing method of an organic EL display device of the first embodiment of this invention.

FIG. 2 is a top view of an evaporation apparatus shown in FIG. 1.

FIG. 3 shows a step of the manufacturing method of an organic EL display device of the first embodiment following the step of FIG. 1.

FIG. 4 shows a step of the manufacturing method of an organic EL display device of the first embodiment following the step of FIG. 3.

FIG. 5 shows a step of the manufacturing method of an organic EL display device of the first embodiment following the step of FIG. 4.

FIG. 6 shows a step of the manufacturing method of an organic EL display device of the first embodiment following the step of FIG. 5.

FIG. 7 is a cross-sectional view of the organic EL element of the first embodiment.

FIG. 8 shows a vacuum evaporation device used in a manufacturing method of an organic EL display device of the second embodiment of the invention.

FIG. 9 is a cross-sectional view of the organic EL element of the second embodiment.

FIGS. 10A and 10B are a plain views of another deposition devices applicable to the first and second embodiments.

FIG. 11 is a plan view showing a conventional EL display device.

FIG. 12A is a cross-sectional view of the EL display device along with the A-A line in FIG. 11, and FIG. 12B is a cross-sectional view of the EL display device along with the B-B line in FIG. 11.

FIGS. 13-16 show steps of a conventional manufacturing method of an organic EL display device.

### DETAILED DESCRIPTION OF THE INVENTION

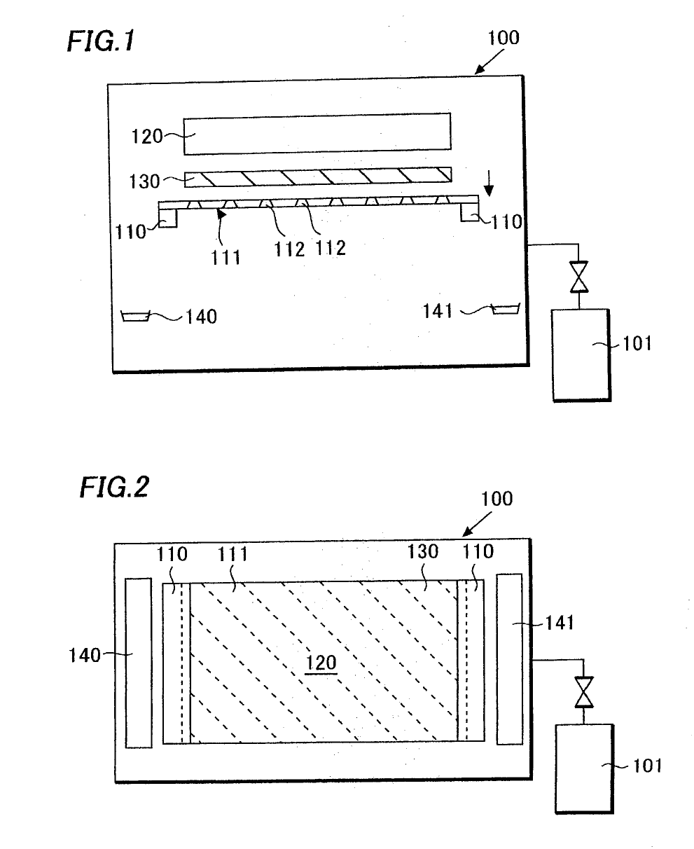

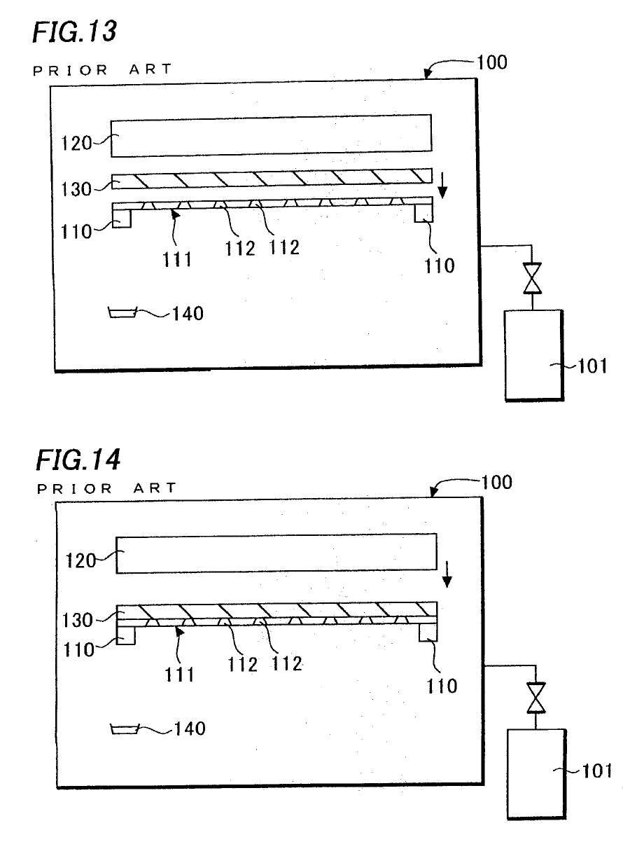

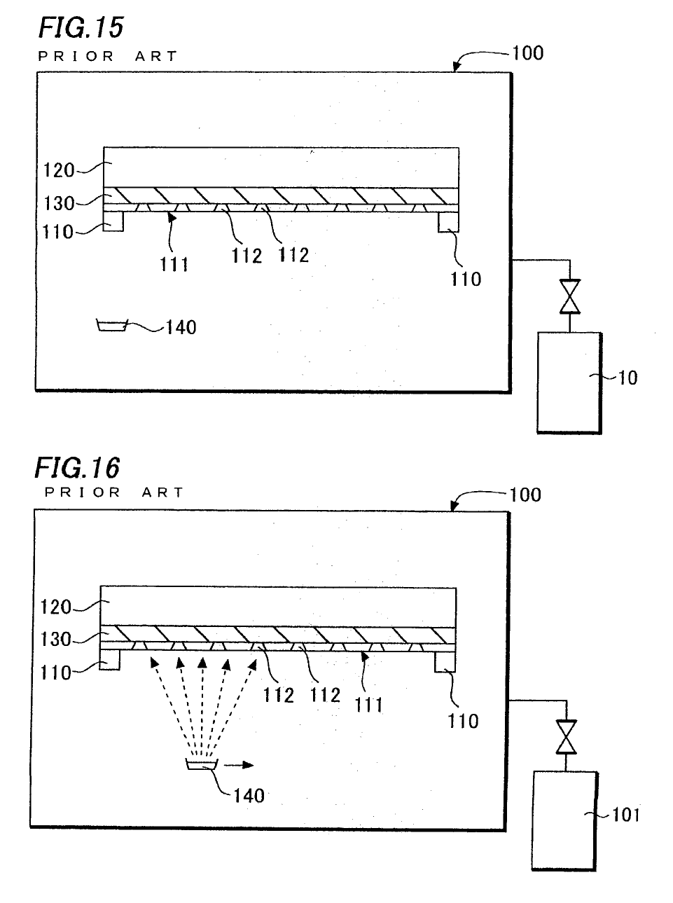

The first embodiment of this invention will be explained by referring to FIGS. 1-7. The same components in the figures as those in FIGS. 13-16 are given the same reference numerals.

A glass substrate 130 is inserted between a magnet 120 and a shadow mask 111 in a chamber of a vacuum evaporation device 100 in FIG. 1. FIG. 2 is a top view of the evaporation device 100 of FIG. 1.

This embodiment employs two evaporation sources 140, 141 that are movable by a moving system (not shown in the figure) in a horizontal direction along the main surface of the glass substrate 130 in the chamber of the vacuum evaporation device 100. The evaporation sources 140, 141 are crucibles extending in a direction perpendicular to its propagation direction and evaporation materials placed in the crucibles. The evaporation material in the crucible is heated by a heater for evaporation.

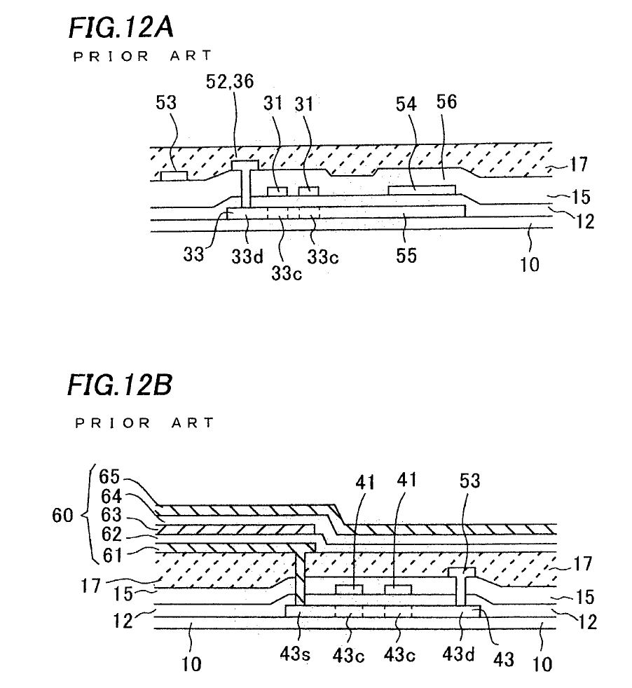

The evaporation source 140 remains at the left edge of the glass substrate 130 and the evaporation source 141 remains at the right edge of the glass substrate 130 before the evaporation begins. The material for an emissive layer is stored in the evaporation source 140 and the material for an electron transportation layer is stored in the evaporation source 141. Other configurations are the same as those shown in FIG. 12. Although they are not shown in the figures, the TFTs, the interlayer insulating film, the planarization film, and the anode made of a transparent electrode such as ITO have been disposed on the pattern forming surface of the glass substrate 130. Also, a hole transportation layer has been formed on the anode through the evaporation method described as a conventional example.

The chamber of the vacuum evaporation device 100 is evacuated by an exhaust system 101 in FIG. 1. The glass substrate 130 is inserted between the magnet 120 and the shadow mask 111 by a transportation system not shown in the figure.

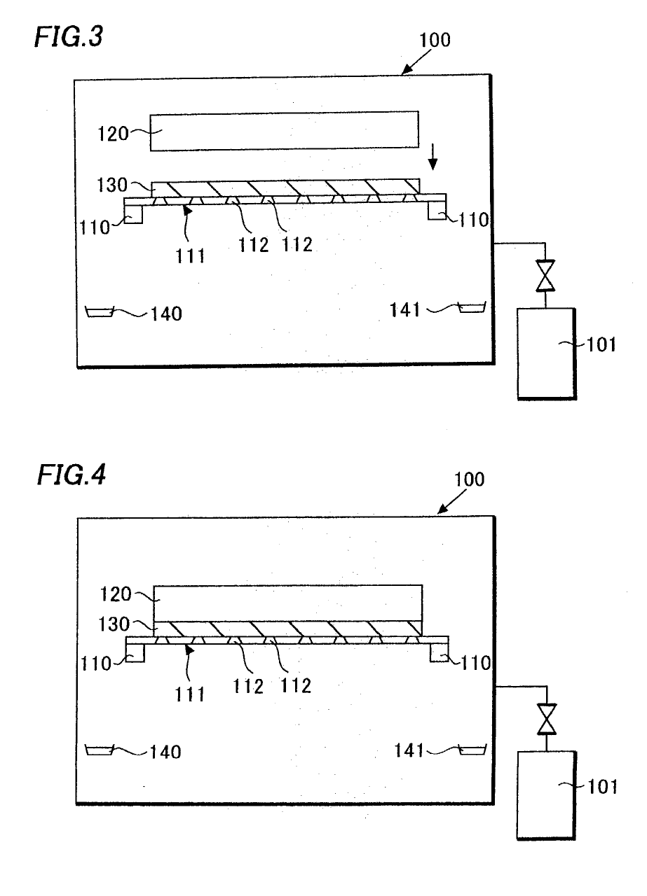

The glass substrate 130 is placed on the shadow mask 111 by the transportation system, as shown in FIG. 3.

Then, the magnet 120 moves downwards till it makes a contact with the upper surface of the glass substrate 130, as shown in FIG. 4. The shadow mask 111, receiving a magnetic power of the magnet 120, is tightly placed on the lower surface, that is the pattern forming surface, of the glass substrate 130.

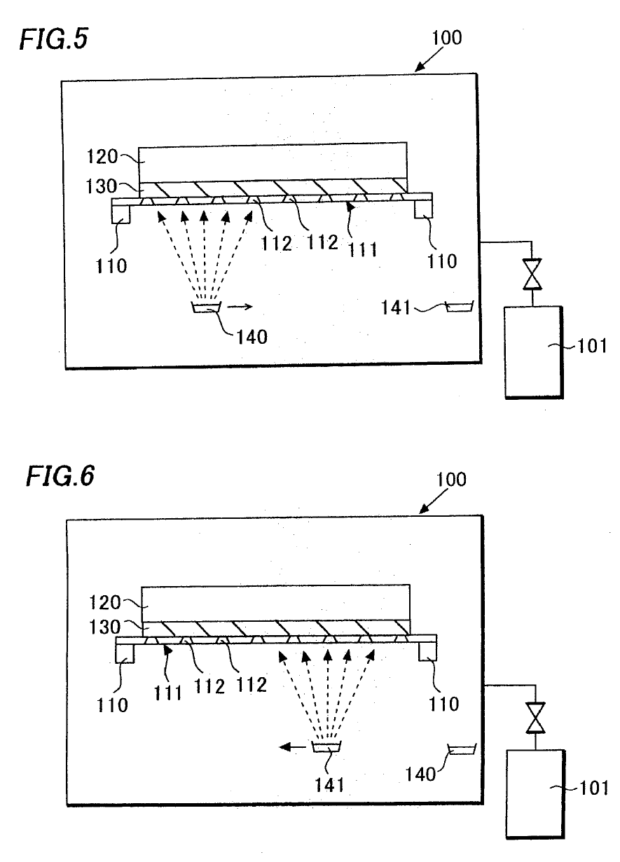

The material for the emissive layer is disposed through evaporation on the surface of the glass substrate 130 through openings 112 formed in the shadow mask 111 while the evaporation source 140 is moved by the moving system not shown in the figure from the left edge to the right edge of the glass substrate 130, as seen from FIG. 5. In this case, the evaporation source 140 includes two evaporation materials, i.e., a host and a dopant.

The evaporation source 140 stops at the right edge of the glass substrate 130, as shown in FIG. 6. Then, the material for the electron transportation layer is disposed through evaporation on the surface of the glass substrate 130 through the same openings 112 formed in the shadow mask 111 while the evaporation source 141 moves in a horizontal direction to the left. The evaporation completes when the evaporation source 141 reaches the left edge of the glass substrate 130.

The emissive layer and the electron transportation layer are continuously disposed by sequentially moving two evaporation sources 140, 141, in this embodiment. Then, the magnet 120 moves upwards. The glass substrate 130 is lifted from the shadow mask 111 and moves to the location for the next process by the transportation system.

The two evaporation sources 140, 141 may move simultaneously to form the emissive layer and the electron transportation layer consecutively. The same material as the material for the emissive layer or the material for the electron transportation layer may be stored in each of the two evaporation sources 140, 141. Further, the material for an electrode, such as the cathode, may be stored in the evaporation sources 140, 141.

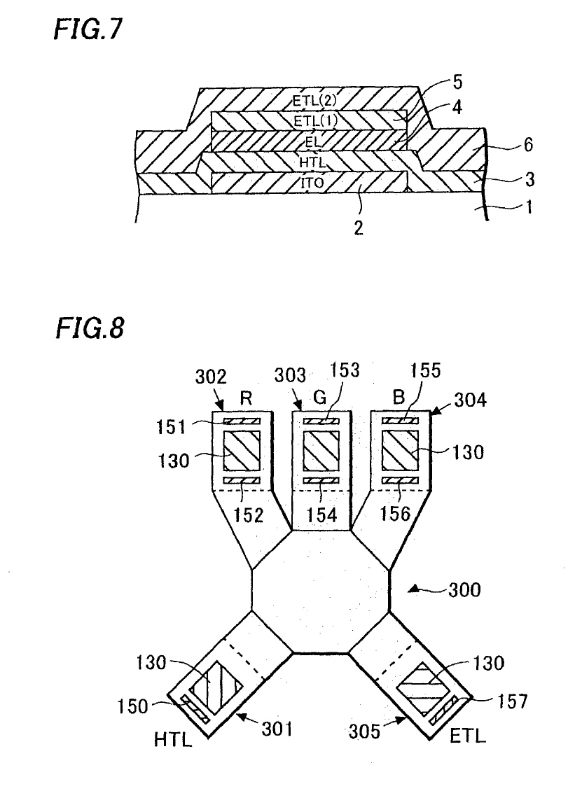

FIG. 7 is a cross-sectional view of the organic EL element formed by the evaporation method described above. The reference numeral 1 denotes a planarization layer formed on the glass substrate, and the reference numeral 2 an anode made of ITO, and the reference numeral 3 a hole transportation layer. The hole transportation layer 3 is commonly used for all the pixels, and formed in the entire display region. The emissive layer 4 and a first electron transportation layer 5 are consecutively disposed on the hole transportation layer 3. Furthermore, a second electron transportation layer 6 is disposed on the first electron transportation layer 5 in the entire display region for commonly used by all the pixels.

According to this embodiment, the emissive layer 4 and the first electron transportation layer 5 are continuously disposed, leading to the improved emissive property of the organic EL element. Also, it is possible to adjust the thickness of and the material for the emissive layer as well as the electron transportation layer for each pixel of R, G, or B. Therefore, it is possible to induce the property of each of the organic EL element of R, G, and B most effectively.

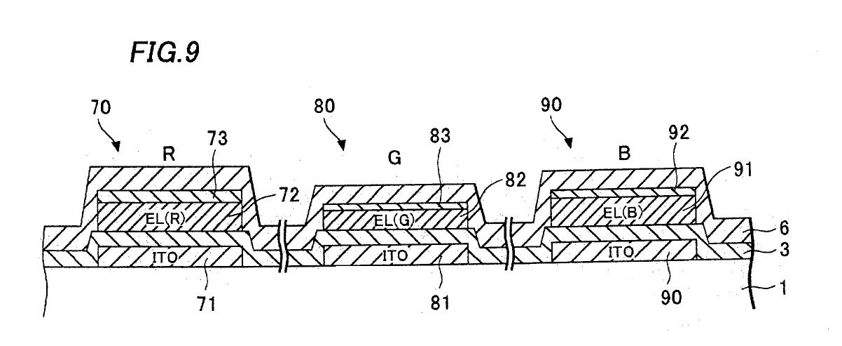

Next, the second embodiment will be explained by referring to FIGS. 8-9. FIG. 8 shows a vacuum evaporation device 300 with multiple chambers. This vacuum evaporation device 300 has five chambers 301, 302, 303, 304, 305. The evaporation of the hole transportation layer 3 on the glass substrate 130 is performed in the chamber 301. Then, the glass substrate 130 is transported to the chamber 302, where the evaporation of the emissive layer and the electron transportation layer for the R pixel is performed. After this, the glass substrate 130 is transported to the chamber 303, where the evaporation of the emissive layer and the electron transportation layer for the G pixel is performed.

Then, the glass substrate 130 is transported to the chamber 304, where the evaporation of the emissive layer and the electron transportation layer for the B pixel is performed. The glass substrate 130 is then transported to the chamber 305, where the evaporation of the electron transportation layer commonly used for all the pixels is further performed.

Evaporation sources 150 and 157 are disposed in the chambers 301 and 305 respectively. Each of the chambers 302, 303 and 304 corresponding to the pixels of R, G and B has two evaporation sources (151, 152), (153, 154), and (155, 156) respectively. Each set of the two evaporation sources moves consecutively or simultaneously to dispose the emissive layer and the electron transportation layer for each pixel through evaporation as in the evaporation method of the first embodiment.

FIG. 9 shows a cross-sectional view of the organic EL element formed through the evaporation method described above. Organic El elements 70, 80, and 90 for the R pixel, the G pixel and the B pixel, respectively, are shown. in the figure, and the TFT for driving is omitted in the figure for the sake of simplicity.

The emissive layer 72 and the electron transportation layer 73 are continuously disposed on the common hole transportation layer 3 formed on the anode 71 in the organic EL element of the R pixel. The common electron transportation layer 6 is further disposed over these layers. Likewise the emissive layer 82 and the electron transportation layer 83 are continuously disposed on the common hole transportation layer 3 formed on the anode 81 in the organic EL element of the G pixel. The common electron transportation layer 6 is further disposed over these layers.

Also, the emissive layer 92 and the electron transportation layer 93 are continuously disposed on the common hole transportation layer 3 formed on the anode 91 in the organic EL element of the B pixel. The common electron transportation layer 6 is further disposed over these layers.

Therefore, according to this embodiment, the emissive layer and the electron transportation layer can be continuously disposed for each of pixels of R, G, and B, leading to the improvement of the emissive property. Also, it is possible to change the thickness and the material of these layers in order to induce the most favorable condition for each of the pixels of R, G, and B.

Although there are provided two evaporation sources, and two layers are continuously disposed in the these embodiments, it is also possible to provide more than three evaporation sources for continuously disposing more than three layers.

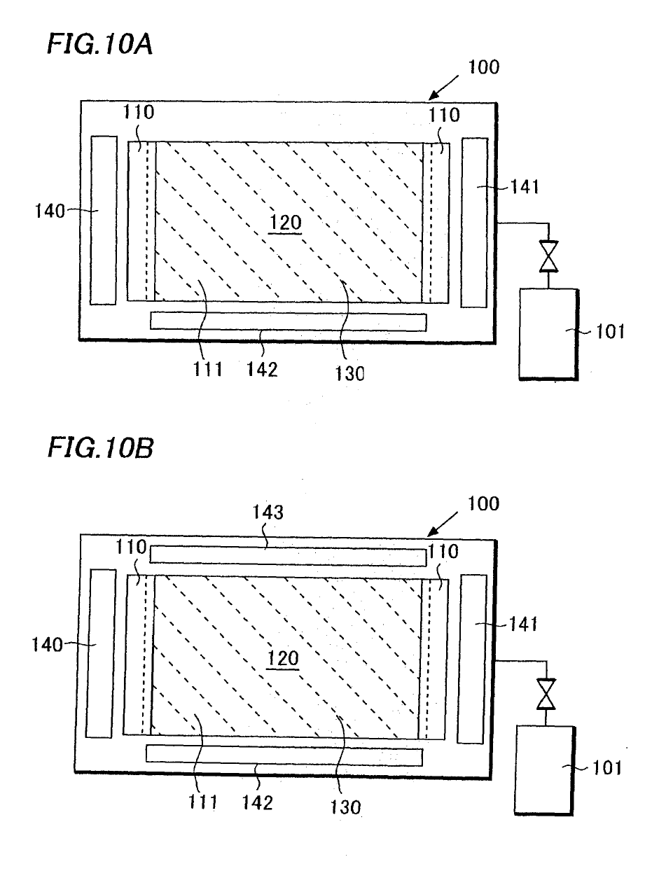

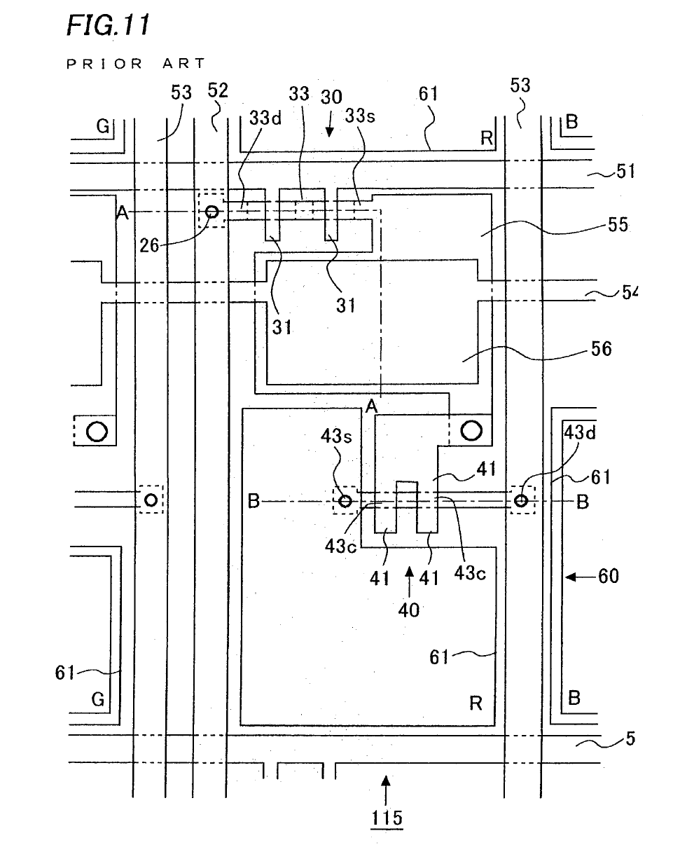

For example, as shown in FIG. 10A, each of the three evaporation sources 140, 141 and 142 moves consecutively or simultaneously to continuously dispose three layers through evaporation. Here, the material for the emissive layer is stored in each of the evaporation sources 140 and 141 and the material for the electron transportation layer is stored in the evaporation source 142. Furthermore, the material for the hole transportation layer may be stored in the evaporation sources 140, the material for the electron transportation layer may be stored in the evaporation sources 141 and the material for the emissive layer may be stored in the evaporation source 142.

Further, four evaporation sources may be used as shown in FIG. 10B. Each of the four evaporation sources 140 ,141, 142 and 143 moves consecutively or simultaneously to continuously dispose four layers through evaporation. For example, the material for the hole transportation layer is stored in the evaporation sources 140, the material for the electron transportation layer is stored in the evaporation sources 141 , the material for the orange color emissive layer is stored in the evaporation source 142, and the material for the blue color emissive layer is stored in the evaporation source 143 in order to form a white color EL element. In this white color EL element, the orange color emissive layer and the blue color emissive layer are stacked on the hole transportation layer.

What is claimed is:

1. An evaporation method comprising:
introducing an evaporation mask and a substrate into a vacuum chamber;
evacuating the vacuum chamber to create a vacuum;
placing the evaporation mask on a surface of the substrate;
moving a first evaporation source having a first evaporation material therein in the vacuum along a first direction to deposit the first evaporation material on the surface of the substrate; and
moving a second evaporation source having a second evaporation material therein in the vacuum along a second direction to deposit the second evaporation material on the first evaporation material deposited on the surface of the substrate.

2. The evaporation method of claim 1, wherein the first direction is equal to the second direction.

3. The evaporation method of claim 1, wherein the moving of the second evaporation source is performed after the moving of the first evaporation source.

4. The evaporation method of claim 1, wherein the moving of the first evaporation source is performed at least partially at the time of the moving of the second evaporation source.

5. The evaporation method of claim 1, wherein the first evaporation material or the second evaporation material comprises an organic electroluminescent material or an electrode material.

6. The evaporation method of claim 1, further comprising moving a third evaporation source having a third evaporation material therein in the vacuum along a third direction to deposit the third evaporation material on the second evaporation material deposited on the second evaporation material.

7. The evaporation method of claim 6, further comprising moving a fourth evaporation source having a fourth evaporation material therein in the vacuum along a fourth direction to deposit the fourth evaporation material on the third evaporation material deposited on the third evaporation material.

8. A manufacturing method of a display device including an electroluminescent element, comprising:
introducing an insulating substrate and an evaporation mask having openings corresponding to a pixel pattern of the display device into a vacuum chamber;
evacuating the vacuum chamber to create a vacuum;
placing the evaporation mask on a surface of the insulating substrate;
moving a first evaporation source having a first constituent material of the electroluminescent element therein in the vacuum along a first direction to deposit the first constituent material on the surface of the insulating substrate; and
moving a second evaporation source having a second constituent material of the electroluminescent element therein in the vacuum along a second direction to deposit the second constituent material on the first constituent material deposited on the surface of the insulating substrate.

9. The manufacturing method of a display device of claim 8, wherein the first direction is equal to the second direction.

10. The manufacturing method of a display device of claim 8, wherein the moving of the second evaporation source is performed after the moving of the first evaporation source.

11. The manufacturing method of a display device of claim 8, wherein the moving of the first evaporation source is performed at least partially at the time of the moving of the second evaporation source.

12. The manufacturing method of a display device of claim 8, wherein the first constituent material is a material for an emissive layer of the electroluminescent element, and the second constituent material is a material for an electron transportation layer of the electroluminescent element.

13. A manufacturing method of a display device including electroluminescent elements corresponding to multiple colors, comprising:
providing a deposition apparatus comprising a first evaporation chamber, a second evaporation chamber and a third evaporation chamber;
introducing an insulating substrate and a pixel mask for a first color having openings corresponding to a pixel pattern of the first color into the first evaporation chamber;
placing the pixel mask for the first color on a surface of the insulating substrate;
moving a first evaporation source of the first color having therein a first constituent material of the electroluminescent element corresponding to the first color along a first direction to deposit the first constituent material of the first color on the surface of the insulating substrate;
moving a second evaporation source of the first color having therein a second constituent material of the electroluminescent element corresponding to the first color along a second direction to deposit the second constituent material of the first color on the first constituent material of the first color deposited on the surface of the insulating substrate;
moving the insulating substrate from the first evaporation chamber to the second evaporation chamber;
introducing a pixel mask for a second color having openings corresponding to a pixel pattern of the second color into the second evaporation chamber;
placing the pixel mask for the second color on the surface of the insulating substrate;
moving a first evaporation source of the second color having therein a first constituent material of the electroluminescent element corresponding to the second color along a third direction to deposit the first constituent material of the second color on the surface of the insulating substrate;
moving a second evaporation source of the second color having therein a second constituent material of the electroluminescent element corresponding to the second color along a fourth direction to deposit the second constituent material of the second color on the first constituent material of the second color deposited on the surface of the insulating substrate;
moving the insulating substrate from the second evaporation chamber to the third evaporation chamber;
introducing a pixel mask for a third color having openings corresponding to a pixel pattern of the third color into the third evaporation chamber;
placing the pixel mask for the third color on the surface of the insulating substrate;
moving a first evaporation source of the third color having therein a first constituent material of the electroluminescent element corresponding to the third color along a fifth direction to deposit the first constituent material of the third color on the surface of the insulating substrate; and
moving a second evaporation source of the third color having therein a second constituent material of the electroluminescent element corresponding to the third color along a sixth direction to deposit the second constituent material of the third color on the first constituent material of the third color deposited on the surface of the insulating substrate.

14. The manufacturing method of a display device of claim 13, wherein the first direction is equal to the second direction.

15. The manufacturing method of a display device of claim 13, wherein the third direction is equal to the fourth direction.

16. The manufacturing method of a display device of claim 13, wherein the fifth direction is equal to the sixth direction.

17. The manufacturing method of a display device of claim 13, wherein the moving of the second evaporation source of the first color is performed after the moving of the first evaporation source of the first color.

18. The manufacturing method of a display device of claim 13, wherein the moving of the first evaporation source of the first color is performed at least partially at the time of the moving of the second evaporation source of the first color.

19. The manufacturing method of a display device of claim 13, wherein the moving of the second evaporation source of the second color is performed after the moving of the first evaporation source of the second color.

20. The manufacturing method of a display device of claim 13, wherein the moving of the first evaporation source of the second color is performed at least partially at the time of the moving of the second evaporation source of the second color.

21. The manufacturing method of a display device of claim 13, wherein the moving of the second evaporation source of the third color is performed after the moving of the first evaporation source of the third color.

22. The manufacturing method of a display device of claim 13, wherein the moving of the first evaporation source of the third color is performed at least partially at the time of the moving of the second evaporation source of the third color.
